(19) United States
(12) Patent Application Publication
(10) Pub. No.: US 2015/0041972 A1
(43) Pub. Date: Feb. 12, 2015

(54) SEMICONDUCTOR PACKAGE AND FABRICATION METHOD THEREOF

(71) Applicant: Siliconware Precision Industries Co., Ltd., Taichung (TW)

(72) Inventors: Chia-Kai Shih, Taichung (TW); Lung-Yuan Wang, Taichung (TW); Cheng-Chia Chiang, Taichung (TW); Chu-Chi Hsu, Taichung (TW); Shih-Hao Tung, Taichung (TW)

(73) Assignee: SILICONWARE PRECISION INDUSTRIES CO., LTD., Taichung (TW)

(21) Appl. No.: 14/249,626

(22) Filed: Apr. 10, 2014

(30) Foreign Application Priority Data
Aug. 12, 2013 (TW) 102128809

(51) Int. Cl. H01L 25/065; H01L 23/00

(52) U.S. Cl. CPC H01L 25/0657; H01L 24/14; H01L 24/97; H01L 2225/06513
USPC 257/737; 438/107

(57) ABSTRACT

A semiconductor package is disclosed, which includes: a first substrate; a first semiconductor component disposed on the first substrate; a second substrate disposed on the first semiconductor component and electrically connected to the first substrate through a plurality of conductive elements; and a first encapsulant formed between the first substrate and the second substrate and encapsulating the first semiconductor component and the conductive elements. The present invention can control the height and volume of the conductive elements since the distance between the first substrate and the second substrate is fixed by bonding the second substrate to the first semiconductor component.

### BACKGROUND OF THE INVENTION

1. Field of the Invention

The present invention relates to package structures, and more particularly, to a semiconductor package and a fabrication method thereof.

2. Description of Related Art

Along with the rapid development of portable electronic products, package on package (PoP) structures have been developed to meet miniaturization, high density and high performance requirements of the portable electronic products.

FIG. 1 is a schematic cross-sectional view of a conventional stack type semiconductor package 1. Referring to FIG. 1, the semiconductor package 1 has a first package structure 1a, a second package structure 1b, and an encapsulant 13 formed between the first package structure 1a and the second package structure 1b for adhesively connecting the first package structure 1a and the second package structure 1b. The first package structure la has a first substrate 10, a first semiconductor component 11 flip-chip bonded to the first substrate 10 through a plurality of conductive bumps 110, and an underfill 111 encapsulating the conductive bumps 110. The second package structure 1b has a second substrate 12, second semiconductor components 14 flip-chip bonded to the second substrate 12 through a plurality of conductive bumps 140, and an underfill 141 encapsulating the conductive bumps 140. The second substrate 12 is stacked on and electrically connected to the first substrate 10 through a plurality of solder balls 120. Further, the solder balls 120 are encapsulated by the encapsulant 13.

However, in the conventional semiconductor package 1, there is a gap between the first package structure la and the second package structure lb and large volume and height errors easily occur to the solder balls 120 after a reflow process. As such, defects may occur to the solder joints and result in a poor electrical connection quality. Further, the solder balls 120 arranged in a grid array may have poor coplanarity such that uneven stresses are applied on the solder joints, thereby easily leading to a tilted bonding between the first and second package structures 1a, 1b and even an offset of the solder joints.

To overcome the drawback of tilted bonding, copper posts can be formed instead of the solder balls 120. However, the copper posts are expensive and not cost-effective.

Furthermore, the underfill 111, 141 formed between the substrates and the semiconductor components incurs a high fabrication cost.

Therefore, there is a need to provide a semiconductor package and a fabrication method thereof so as to overcome the above-described drawbacks.

### SUMMARY OF THE INVENTION

In view of the above-described drawbacks, the present invention provides a semiconductor package, which comprises: a first substrate; at least a first semiconductor component disposed on the first substrate; a second substrate disposed on the at least a first semiconductor component and electrically connected to the first substrate through a plurality of conductive elements; and a first encapsulant formed between the first substrate and the second substrate and encapsulating the at lease a first semiconductor component and the conductive elements.

The present invention further provides a fabrication method of a semiconductor package, which comprises the steps of: providing a first substrate having at least a first semiconductor component disposed thereon; disposing a second substrate on the at lease a first semiconductor component and electrically connecting the second substrate and the first substrate through a plurality of conductive elements; and forming between the first substrate and the second substrate a first encapsulant that encapsulates the at least a first semiconductor component and the conductive elements.

Before disposing the second substrate on the first semiconductor component, the above-described method can further comprise singulating the second substrate

In an embodiment, the method further comprises performing a singulation process to obtain a plurality of semiconductor packages.

In an embodiment, the first semiconductor component is disposed on the first substrate through a plurality of conductive bumps, and the conductive bumps can be encapsulated by the first encapsulant.

In an embodiment, the first encapsulant adhesively connects the first substrate and the second substrate.

In an embodiment, a bonding layer is formed on the first semiconductor component and bonds the second substrate to the first semiconductor component.

In an embodiment, at least a second semiconductor component is further disposed on the second substrate, and a second encapsulant is further formed on the second substrate and encapsulates the at least a second semiconductor component.

In an embodiment, at least a package can be disposed on the second substrate.

Therefore, since the distance between the first substrate and the second substrate is fixed by bonding the second substrate to the first semiconductor component, the present invention can control the height and volume of the conductive elements so as to avoid any defect of the conductive elements. As such, the present invention overcomes the conventional drawbacks of poor electrical connection quality, poor coplanarity and tilted bonding, improves the product yield and dispenses with the costly copper posts.

Further, by filling the first encapsulant between the first substrate and the at least a first semiconductor component to encapsulate the conductive bumps, the present invention eliminates the need of an underfill, thereby saving the material cost.

### BRIEF DESCRIPTION OF DRAWINGS

FIG. 1 is a schematic cross-sectional view of a conventional stack type semiconductor package; and

FIGS. 2A to 2D are schematic cross-sectional views showing a fabrication method of a semiconductor package according to the present invention, wherein FIG. 2B′ shows another embodiment of FIG. 2B and FIG. 2D′ shows another embodiment of FIG. 2D.

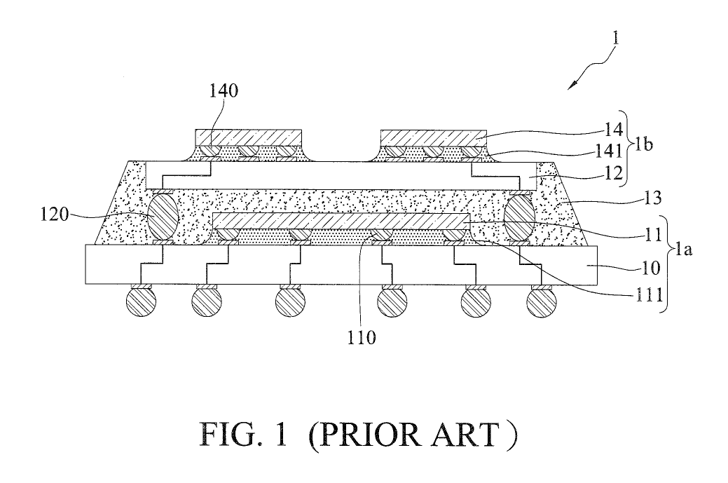

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “lower”, “on”, “a” etc. are merely for illustrative purposes and should not be construed to limit the scope of the present invention.

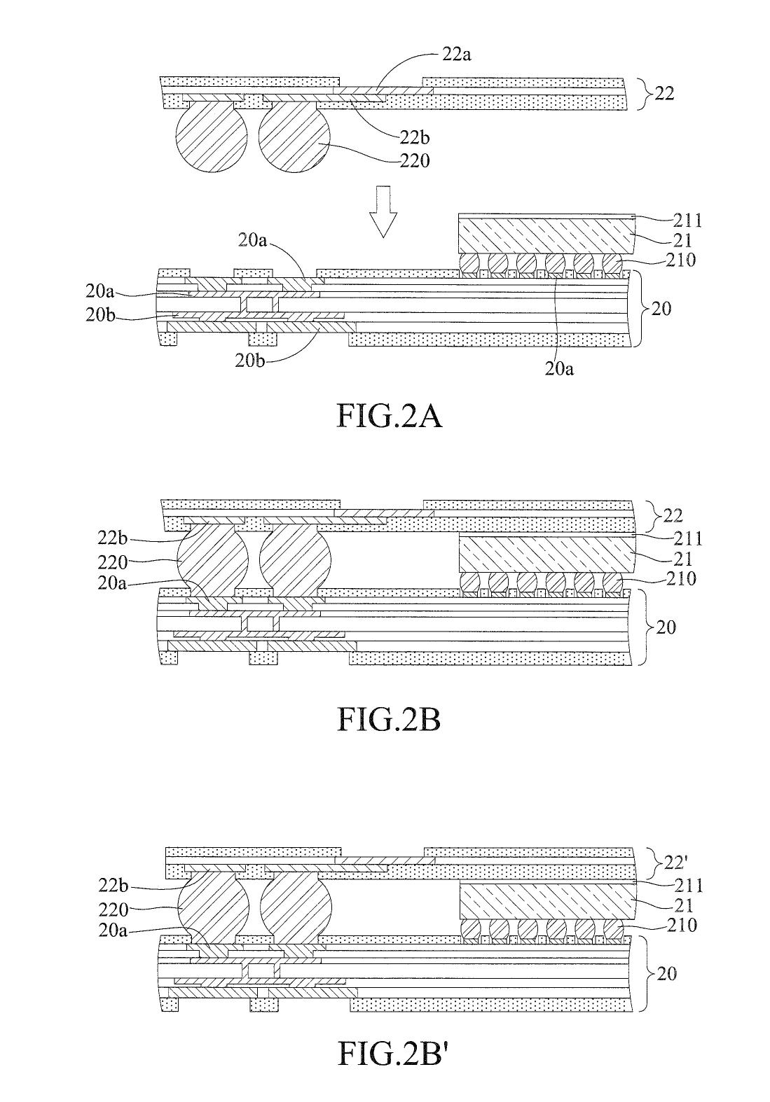

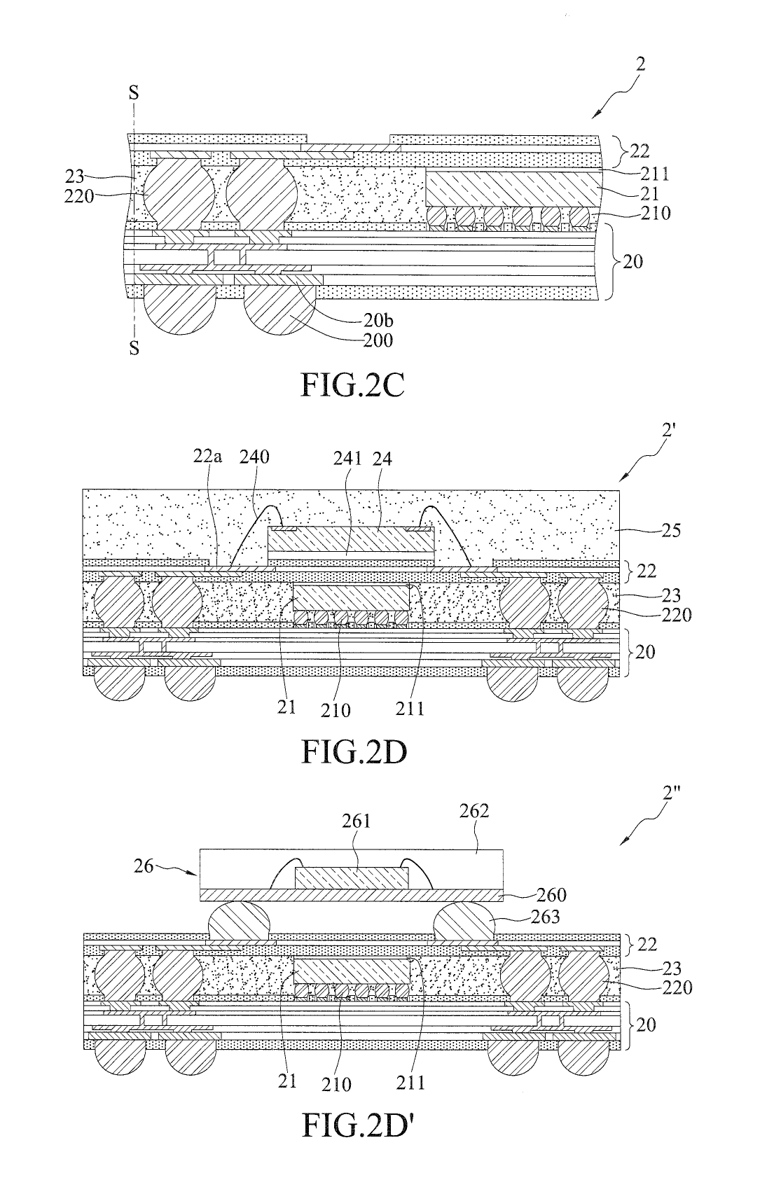

FIGS. 2A to 2D are schematic cross-sectional views showing a fabrication method of a semiconductor package 2 according to the present invention.

Referring to FIG. 2A, a first substrate 20 and a second substrate 22 are provided. The first substrate 20 has at least a first semiconductor component 21 disposed thereon, and a bonding layer 211 made of a non-conductive material is formed on the first semiconductor component 21. The second substrate 22 has a plurality of conductive elements 220 formed on a lower side thereof.

In the present embodiment, the first and second substrates 20, 22 are circuit boards.

The first substrate 20 has a first circuit layer 20a and a second circuit layer 20b respectively formed on upper and lower sides thereof. The second substrate 22 has a first circuit layer 22a and a second circuit layer 22b respectively formed on upper and lower sides thereof. But it should be noted that the first and second substrates 20, 22 can be any carriers for carrying chips without any special limitation.

The first semiconductor component 21 is disposed on the first circuit layer 20a of the first substrate 20 through a plurality of conductive bumps 210.

The conductive elements 220 are made of a solder material and formed on the second circuit layer 22b of the second substrate 22.

Referring to FIG. 2B, the second substrate 22 is bonded to the first semiconductor component 21 through the bonding layer 211 and supported on the first substrate 20 by the conductive elements 220. Further, the first circuit layer 20a of the first substrate 20 and the second circuit layer 22b of the second substrate 22 are electrically connected through the conductive elements 220.

In the present embodiment, the bonding layer 211 on the first semiconductor component 21 provides preferred bonding and supporting effects to the second substrate 22.

In another embodiment, referring to FIG. 2B′, the second substrate 22 can be singulated to obtain a second substrate 22′ first and then the second substrate 22′ is bonded to the first semiconductor component 21.

Referring to FIG. 2C, a first encapsulant 23 is formed on the upper side of the first substrate 20 and the lower side of the second substrate 22 for adhesively connecting the first and second substrates 20, 22 and encapsulating the first semiconductor component 21, the conductive elements 220 and the conductive bumps 210.

Thereafter, a singulation process is performed along a cutting path S to obtain a plurality of semiconductor packages 2.

In the present embodiment, no encapsulant is formed between the second substrate 22 and the first semiconductor component 21 due to the bonding layer 211.

Further, a plurality of conductive elements such as solder balls 200 can be formed on the second circuit layer 20b of the first substrate 20 for mounting an electronic structure such as a circuit board.

Referring to FIG. 2D, subsequently, at least a second semiconductor component 24 is disposed on the upper side of the second substrate 22 through a bonding layer 241 and a second encapsulant 25 is formed on the upper side of the second substrate 22 for encapsulating the second semiconductor component 24, thereby forming a semiconductor package 2′.

In the present embodiment, the second semiconductor component 24 is electrically connected to the first circuit layer 22a on the upper side of the second substrate 22 through a plurality of bonding wires 240. Further, the bonding wires 240 are encapsulated by the second encapsulant 25. In other embodiments, the second semiconductor component 24 can be flip-chip disposed on the upper side of the second substrate 22.

In an alternative embodiment, the singulation process of FIG. 2C can be performed after the processes of FIG. 2D.

Referring to FIG. 2D′, at least a package 26 can be disposed on the second substrate 22 to form a semiconductor package 2″. A singulation process can be performed before or after this process.

In the present embodiment, the package 26 has a carrier 260, a third semiconductor component 261 disposed on and electrically connected to the carrier 260 and an encapsulant 262 encapsulating the third semiconductor component 261.

Further, the carrier 260 is electrically connected to the second substrate 22 through a plurality of conductive elements 263 such as solder balls. In addition, the third semiconductor component 261 can be electrically connected to the carrier 260 through wire bonding (as shown in FIG. 2D′) or in a flip-chip manner or embedded in the carrier 260.

According to the present invention, the second substrate 22 is bonded to the first semiconductor component 21 and therefore the distance between the second substrate 22 and the first substrate 20 is fixed. As such, the height and volume of the conductive elements 220 can be controlled so as to prevent any defect from occurring to the solder joints after a reflow process is performed to the conductive elements 220, thereby improving the electrical connection quality. Further, the conductive elements 220 arranged in a grid array have good coplanarity. Consequently, even stresses can be applied on the solder joints so as to avoid tilted bonding between the substrates and offset of the solder joints. Therefore, the present invention improves the product yield and dispenses with the costly copper posts.

Further, by filling the first encapsulant 23 between the first substrate 20 and the first semiconductor component 21 to encapsulate the conductive bumps 210, the present invention eliminates the need of an underfill as in the prior art, thereby saving the material cost.

The present invention further provides a semiconductor package 2, 2′, 2″, which has: a first substrate 20; a first semiconductor component 21 disposed on the first substrate 20; a second substrate 22 disposed on the first semiconductor component 21 and electrically connected to the first substrate 20 through a plurality of conductive elements 220; and a first encapsulant 23 formed between the first substrate 20 and the second substrate 22.

The first semiconductor component 21 is disposed on the first substrate 20 through a plurality of conductive bumps 210.

The first encapsulant 23 adhesively connects the first substrate 20 and the second substrate 22 and encapsulates the first semiconductor component 21, the conductive bumps 210 and the conductive elements 220.

In an embodiment, a bonding layer 211 is formed on the first semiconductor component 21 for bonding the second substrate 22 to the first semiconductor component 21. The bonding layer 211 is located between the first semiconductor component 21 and the second substrate 22.

In an embodiment, referring to FIG. 2D, the semiconductor package 2′ further has a second semiconductor component 24 disposed on the second substrate 22 and a second encapsulant 25 formed on the second substrate 22 for encapsulating the second semiconductor component 24.

In an embodiment, referring to FIG. 2D′, the semiconductor package 2″ further has at least a package 26 disposed on the second substrate 22. The package 26 has a carrier 260, a third semiconductor component 261 disposed on and electrically connected to the carrier 260, and an encapsulant 262 encapsulating the third semiconductor component 261.

Therefore, since the distance between the first substrate and the second substrate is fixed by bonding the second substrate to the first semiconductor component, the present invention can control the height and volume of the conductive elements so as to improve the electrical connection quality and ensure a good coplanarity of the conductive elements. Consequently, even stresses can be applied on the joints to avoid tilted bonding between the substrates. Therefore, the present invention improves the product yield and dispenses with the costly copper posts.

Further, by filling the first encapsulant between the first substrate and the first semiconductor component to encapsulate the conductive bumps, the present invention eliminates the need of an underfill, thereby saving the material cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A semiconductor package, comprising:
a first substrate;
at least a first semiconductor component disposed on the first substrate;
a second substrate disposed on the at least a first semiconductor component and electrically connected to the first substrate through a plurality of conductive elements; and
a first encapsulant formed between the first substrate and the second substrate and encapsulating the at least a first semiconductor component and the conductive elements.

2. The semiconductor package of claim 1, wherein the at least a first semiconductor component is disposed on the first substrate through a plurality of conductive bumps, and the conductive bumps are encapsulated by the first encapsulant.

3. The semiconductor package of claim 1, wherein the first encapsulant adhesively connects the first substrate and the second substrate.

4. The semiconductor package of claim 1, further comprising a bonding layer formed on the at least a first semiconductor component for bonding the second substrate to the at least a first semiconductor component

5. The semiconductor package of claim 1, further comprising at least a second semiconductor component disposed on the second substrate.

6. The semiconductor package of claim 5, further comprising a second encapsulant formed on the second substrate and encapsulating the at least a second semiconductor component.

7. The semiconductor package of claim 1, further comprising at least a package disposed on the second substrate.

8. A fabrication method of a semiconductor package, comprising the steps of:
providing a first substrate having at least a first semiconductor component disposed thereon;
disposing a second substrate on the at least a first semiconductor component and electrically connecting the second substrate and the first substrate through a plurality of conductive elements; and
forming between the first substrate and the second substrate a first encapsulant that encapsulates the at least a first semiconductor component and the conductive elements.

9. The fabrication method of claim 8, wherein the at least a first semiconductor component is disposed on the first substrate through a plurality of conductive bumps and the conductive bumps are encapsulated by the first encapsulant.

10. The fabrication method of claim 8, wherein the first encapsulant adhesively connects the first substrate and the second substrate.

11. The fabrication method of claim 8, before disposing the second substrate on the first semiconductor component, further comprising forming on the at least a first semiconductor component a bonding layer for bonding the second substrate to the at least a first semiconductor component.

12. The fabrication method of claim 8, before disposing the second substrate on the at least a first semiconductor component, further comprising singulating the second substrate.

13. The fabrication method of claim 8, further comprising performing a singulation process to obtain a plurality of the semiconductor packages.

14. The fabrication method of claim 8, further comprising disposing at least a second semiconductor component on the second substrate.

15. The fabrication method of claim 14, further comprising forming on the second substrate a second encapsulant that encapsulates the at least a second semiconductor component.

16. The fabrication method of claim 15, further comprising performing a singulation process to obtain a plurality of semiconductor packages.

17. The fabrication method of claim 8, further comprising disposing at least a package on the second substrate.

18. The fabrication method of claim 17, further comprising performing a singulation process to obtain a plurality of semiconductor packages.
